(19) United States
(12) Patent Application Publication
(10) Pub. No.: US 2024/0304117 A1
(43) Pub. Date: Sep. 12, 2024

(54) Easily Curved LED Display Module

(71) Applicant: DESIGNLED TECHNOLOGY CORP., El Monte, CA (US)

(72) Inventors: Ligang ZHAO, El Monte, CA (US); Lei LIANG, El Monte, CA (US); Chengwei MA, El Monte, CA (US); Guangming SONG, El Monte, CA (US)

(21) Appl. No.: 18/179,947

(22) Filed: Mar. 7, 2023

(51) Int. Cl. G09F 9/30; G09F 9/33; H01L 25/075; H05K 1/02

(52) U.S. Cl. CPC G09F 9/301; G09F 9/33; H01L 25/0753; H05K 1/0278

(57) ABSTRACT

The patent application discloses an easily curved LED system. The LED system may comprise a printed circuit board (“PCB”). The PCB may have at least one layer. An aperture through all layers of the PCB may exist and may be interposed between a location for a LED at a first side of the PCB and a location for a chipset on a second side PCB board.

### TECHNICAL FIELD

This invention concerns a display system, in particular, this invention concerns an easily curved LED display module.

### BACKGROUND

An easily curved LED display module is a type of LED panel that is designed to be flexible and can be bent into various curved shapes.

Easily curved LED display modules are commonly used in commercial settings for digital signage, such as in shopping malls, airports, and stadiums. They can also be used in creative installations, such as for artistic displays or in stage backdrops.

One benefit of easily curved LED display modules is that they allow for greater creative freedom in designing digital displays. They can be used to create dynamic, immersive experiences that traditional flat screens cannot achieve.

In summary, easily curved LED display modules offer a versatile, innovative solution for creating immersive, dynamic displays in a wide range of settings.

### SUMMARY

In one aspect, one embodiment discloses a system. The system may comprise a printed circuit board (“PCB”) having at least one layer; and an aperture through all layers of the PCB interposed between a location for a LED at a first side of the PCB and a location for a chipset on a second side PCB board.

Optionally in any aspect, the aperture is filled with an insulating medium selected from a group comprising of air and a material which is softer than that of PCB board.

Optionally in any aspect, the aperture is at least one of round dot, a rod, or a cross.

Optionally in any aspect, the aperture does not extend to an edge of the PCB.

Optionally in any aspect, the ratio of the area occupied by the apertures over the area of PCB outer surface ranges from about 6% to about 12%, for example.

Optionally in any aspect, wherein the round dot has about a diameter about 1.3 mm.

Optionally in any aspect, the rod comprises horizontal rods and vertical rods.

Optionally in any aspect, wherein the horizontal rod and vertical rods are about 4.1 mm and 3.1 mm in length respectively.

In further another aspect, a LED system may comprise a substrate, at least one LED mounted onto a surface of the substrate. The substrate may have a plurality of chipsets. An aperture through the substrate may be interposed between the plurality of chipsets on the substrate and the at least one LED.

Optionally in any aspect, the substrate is a PCB.

Optionally in any aspect, the aperture is designed to reduce tension of the PCB so that PCB is easily bent.

Optionally in any aspect, the aperture is filled with an insulating medium selected from a group comprising of air and a material which is softer than that of PCB board.

Optionally in any aspect, the aperture does not extend to an edge of the PCB.

Optionally in any aspect, the aperture is at least one of round dot, a rod, or a cross.

Optionally in any aspect, the rod comprises horizontal rods and vertical rods.

Optionally in any aspect, the ratio of the area occupied by the apertures over the area of PCB outer surface ranges from about 6% to about 12%.

In still further another aspect, one embodiment discloses a method. The method may comprise steps of cutting an aperture through a printed circuit board (“PCB”) via both sides to form a through hole, interposed between a location for a LED at a first side of the PCB and a location for a chipset on a second side PCB board.

Optionally in any aspect the ratio of the area occupied by the apertures over the area of PCB outer surface ranges from about 6% to about 12%.

Optionally in any aspect, the step may further comprise steps of reducing the tensile stress related to bending the PCB via the aperture.

### BRIEF DESCRIPTION OF THE DRAWINGS

In order to illustrate the technical solutions more clearly in the embodiments of the present disclosure or the exemplary techniques, the drawings to be used in the embodiments or the description of the exemplary embodiments will be briefly described below. Obviously, the drawings in the following description are only certain embodiments of the present disclosure, and other drawings may be obtained according to the structures shown in the drawings without any creative work for those skilled in the art.

FIG. 1 is a plan back view of a LED system with a PCB as a substrate according to one exemplary embodiment;

FIG. 2 is a perspective front view of a LED with a substrate according to one exemplary embodiment;

FIG. 3 is a plan view of a LED with a plurality of round dot apertures according to one embodiment;

FIG. 4 is a plan view of a LED with a plurality of horizontal rod apertures according to another embodiment and

FIG. 5 is a plan view of a LED with a plurality of vertical rod apertures according to further another embodiment.

The implementation, functional features and advantages of the present disclosure will be further described with reference to the accompanying drawings.

### DETAILED EMBODIMENTS

### Definitions

The invention is not limited to the particular methodology, protocols, and reagents described herein because they may vary. Further, the terminology used herein is for the purpose of describing particular embodiments only and is not intended to limit the scope of the present invention. As used herein and in the appended claims, the singular forms “a,” “an,” and “the” include plural reference unless the context clearly dictates otherwise.

Unless defined otherwise, all technical and scientific terms and any acronyms used herein have the same meanings as commonly understood by one of ordinary skill in the art in the field of the invention. Although any methods and materials similar or equivalent to those described herein can be used in the practice of the present invention, the preferred methods, devices, and materials are described herein. The technical means, creative features, objectives, and effects of the patent application may be easy to understand, the following embodiments will further illustrate the patent application. However, the following embodiments are only the preferred embodiments of the utility patent application, not all of them. Based on the examples in the implementation manners, other examples obtained by those skilled in the art without creative work shall fall within the protection scope of the present invention. The experimental methods in the following examples are conventional methods unless otherwise specified. The materials used in the following examples can be obtained from commercial sources unless otherwise specified.

### THE EMBODIMENTS

Embodiments of the present invention are directed to LED modules for a spherical display device, and software for implementing the LED modules.

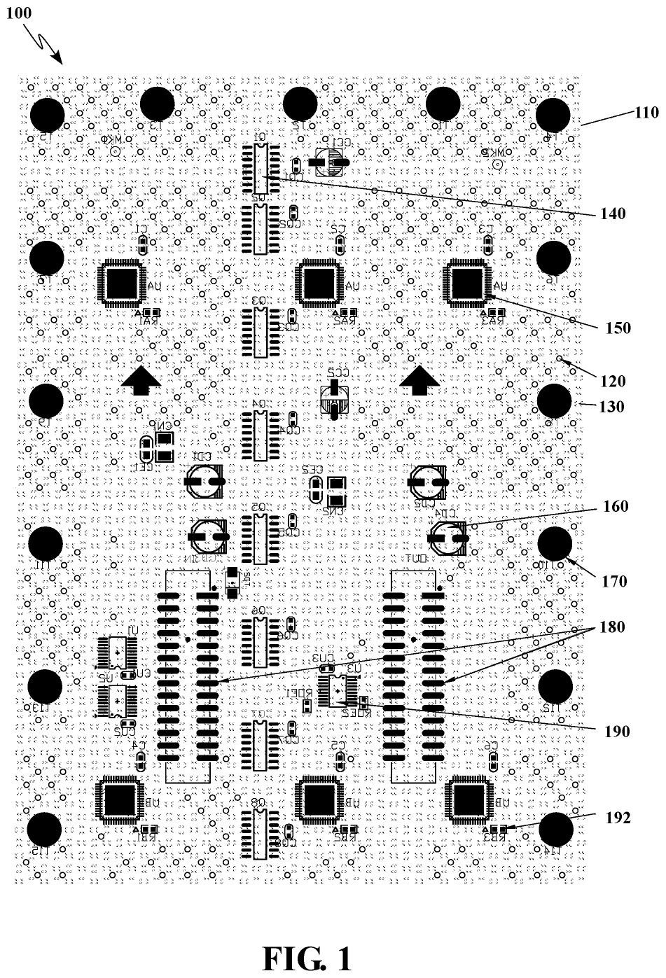

Referring first to FIG. 1, a back side of a system 100 may comprise a printed circuit board (“PCB”) 110. The PCB 110 may have at least one layer and an aperture 120 through all layers of the PCB 110 interposed between a location for a LED 130 at a first side of the PCB 110 and a location for a chipset, such as 8-channel PMOS 140, driver IC 150, capacitor 160, two sockets 180, 74HC245 190, and resistance 192, etc. The PCB 110 may further include a plurality of magnets 170, which can help the PCB 110 to stick to a substrate or support (not shown), which may be made of iron (Fe). However, PCB 110 may also include numerous other integrated circuits and devices. Integrated circuits may create heat which may spread across PCB 110. PCB 110 may also include conductive traces. Traces are generally designed to electrically contact conductive portions of the electronic components mounted on the PCB, thereby forming electrical interconnects. Traces are etched into PCB 110 during PCB 110's fabrication and are made of, for example, copper. The PCB 110 can be rectangular or a quadrilateral shape or other shapes.

The aperture 120 may be filled with an insulating medium selected from a group comprising of air and a material which is softer than that of PCB 110. However, the material or insulating mediums inside the aperture 120 other than air may be used. For example, any insulating material that is resistant to electron motion may be used as aperture 120. However, air provides adequate insulation at significantly less cost. If an insulator other than air is used, such an insulator would preferably (but not necessarily) have a coefficient of conduction less than that of air to provide better thermal insulation than air. The PCB 110 may be made of FR4 materials and thickness may be less than 0.6 mm, for example. FR-4 is the primary insulating backbone upon which the vast majority of rigid printed circuit boards (PCBs) are produced. A thin layer of copper foil is laminated to one or both sides of an FR-4 glass epoxy panel. These are commonly referred to as copper-clad laminates.

FR-4 copper-clad sheets are fabricated with circuitry interconnections etched into copper layers to produce printed circuit boards. More sophisticated and complex FR-4 printed circuit boards are produced in multiple layers, also known as multilayer circuitry.

The aperture 120 does not extend to an edge 194 of the PCB 110 so that the PCB 110 is not easily damages if it is bent.

The density of the aperture 120 on the PCB 110, (may refer to how many apertures per square inch). ranges from about 6% to about 12%, for example. In another words, the ratio of the area occupied by the apertures over the area of PCB outer surface ranges from about 6% to about 12%.

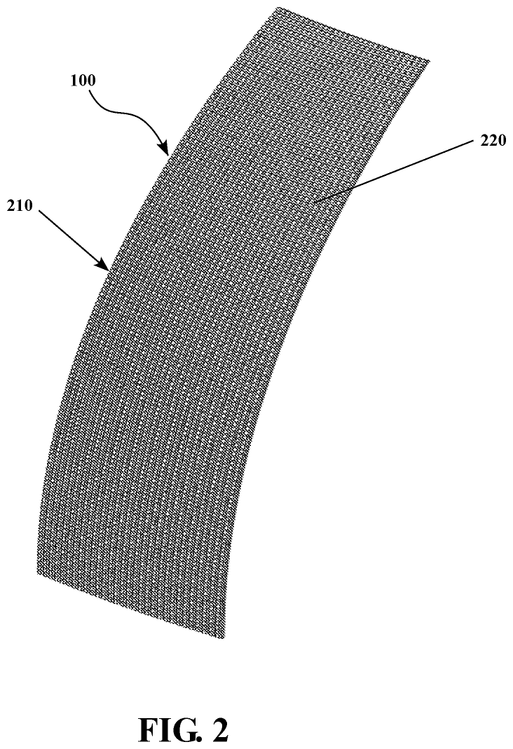

As shown in FIG. 2, the front side 210 of the PCB 110 of the system 100 has a plurality of LEDs on the surface 220 of the PCB 110 and a plurality of apertures 120. The system 100 may be bent easily because the apertures 120 has reduced tensile stress of the PCB 110.

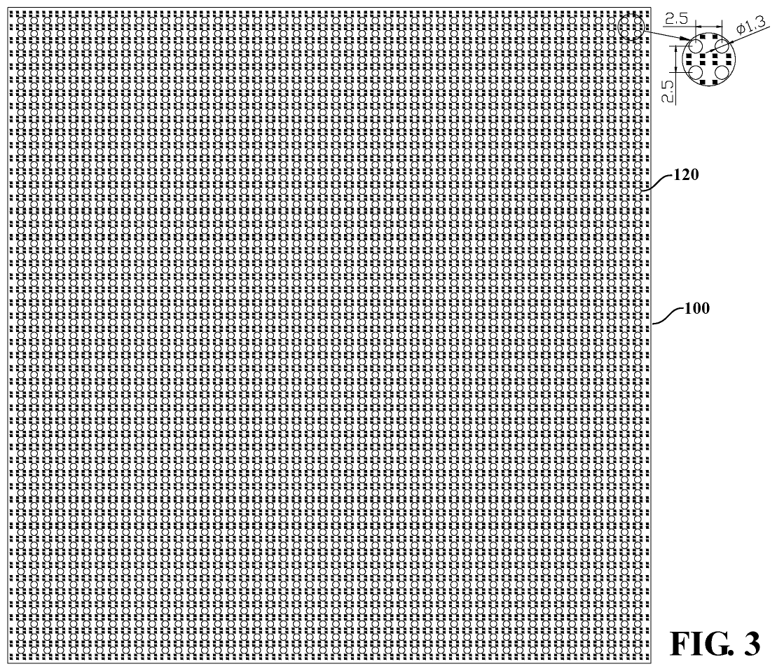

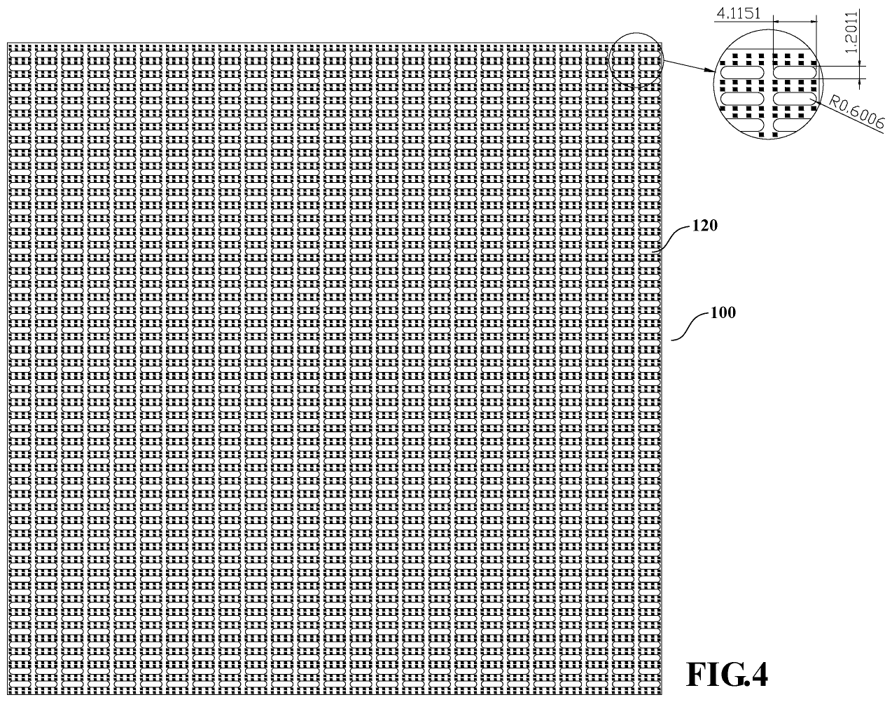

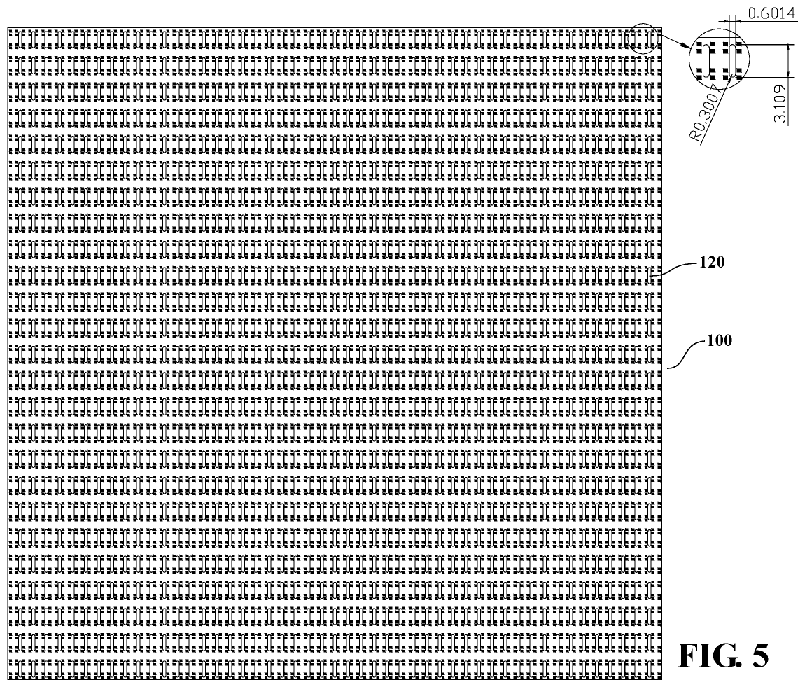

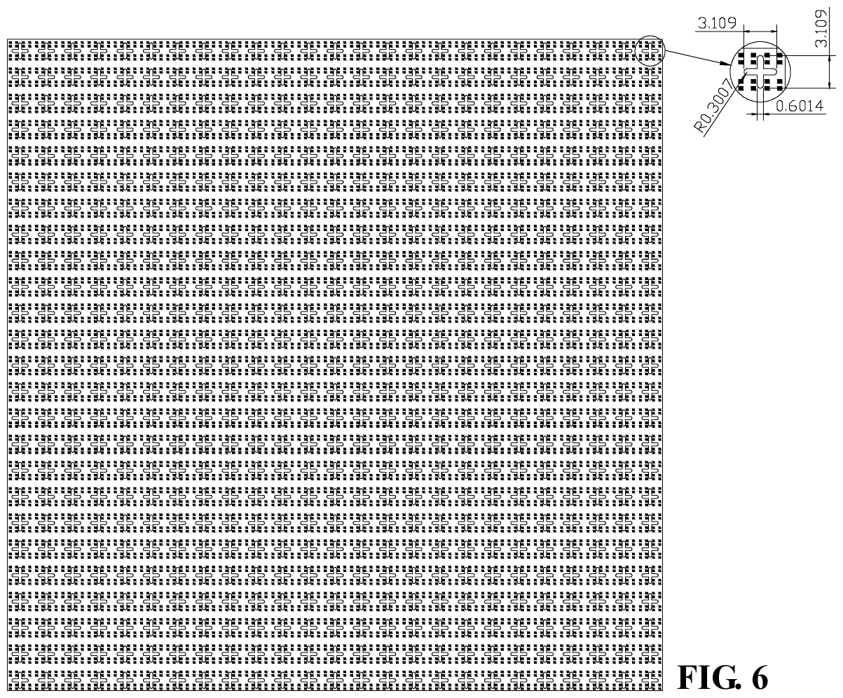

The aperture 120 may be in a round dot as shown in FIG. 3, a rod, which comprises horizontal rods as shown in FIG. 4 and vertical rods as shown in FIG. 5, a cross as shown in FIG. 6, for example.

More specifically, in FIG. 3, the aperture 120 in the system 100 may have 1.3 mm diameter, for example. The distance between the round dot may be about 2.5 mm, for example. In FIG. 4, the horizontal rods may be about 4.12 mm long, about 1.201 mm thick, with a semi-circle end (a radius of about 0.6 mm, for example). In FIG. 5, the vertical rods may be about 3.11 mm long, about 0.601 mm thick, with a semi-circle end (a radius of about 0.301 mm, for example). In FIG. 5, the aperture 120 may be a cross, comprising a vertical rod and horizontal rod, for example. The horizontal rod may be 3.11 mm long, with a semi-circle end (a radium of about 0.301 mm, for example). The vertical rod may be 3.11 mm long with a 0.601 mm thick.

In one embodiment, a method may comprise steps of cutting an aperture through a printed circuit board (“PCB”) via both sides to form a through hole, interposed between a location for a LED at a first side of the PCB and a location for a chipset on a second side PCB board. In one embodiment, the method may further include steps of reducing the tensile stress related to the PCB.

In some embodiments, aperture 120 may be created using a drill or routing bit to cut through PCB 110 in the area in which no copper is present. This is performed at the time the final outer shape of PCB 110 is cut. However, aperture 120 need not be cut out of PCB 110. For example, a mold may include aperture 120 as part of PCB 110 when PCB 110 is manufactured. In various embodiments, aperture 120 may not extend to PCB 110's edge. Air fills aperture 120 and is used to alleviate tensions built up when PCB 110 is bent. However, insulating mediums other than air may be used. For example, any insulating material that is resistant to electron motion may be used as aperture 110. However, air provides adequate insulation at significantly less cost. If an insulator other than air is used, such an insulator would preferably (but not necessarily) have a coefficient of conduction less than that of air to provide better thermal insulation than air.

In some embodiments, aperture 120 corresponds to the width of the drill bit used to cut the aperture. Thus, the minimum width of aperture 120 (represented in FIG. 4 by 120) may be equal to the diameter of the drill bit that cut it. However, the width of aperture 120 is not limited to being the diameter of the drill bit. The width of aperture 120 may be as wide or as thin as the user wishes, so long as the cut is made completely through all layers of PCB 110. For example, an aperture 120 cut using a laser may be less than one mil ( 1/1000 of an inch) wide, but may still work to alleviate the tensions on the PCB 110.

In some embodiment, the ratio of the area occupied by the apertures 120 over the area of PCB 110 outer surface ranges from about 6% to about 12%.

### EXPERIMENTAL

A PCB having width about 150 mm is tested on tensile strength. The PCB subjected to test was bent with radius about 360 mm. The test results had shown that the tensile strength for PCB without apertures had 3.9 N. The tensile strength for PCB with apertures had 2.0 N. From above result, the tensile strength has been decreased 50% by having apertures on the PCB.

It will be appreciated by persons skilled in the art that numerous variations and/or modifications may be made to the invention as shown in the specific embodiments without departing from the scope of the invention as broadly described. The present embodiments are, therefore, to be considered in all respects as illustrative and not restrictive.

The above shows and describes the basic principles, main features and advantages of the patent application. Those skilled in the industry should understand that the present patent application is not limited by the above-mentioned embodiments. The above-mentioned embodiments and the description are only preferred examples of the present patent application and are not intended to limit the present patent application, without departing from the present utility patent application. Under the premise of spirit and scope, the present utility patent application will have various changes and improvements, and these changes and improvements fall within the scope of the claimed utility patent application. The scope of protection claimed by the utility patent application is defined by the appended claims and their equivalents.

We claim:

1. A system, comprising:
a printed circuit board (“PCB”) having at least one layer; and an aperture through all layers of the PCB interposed between a location for a LED at a first side of the PCB and a location for a chipset on a second side PCB board.

2. The system of claim 1, wherein the aperture is filled with an insulating medium selected from a group comprising of air and a material which is softer than that of PCB board.

3. The system of claim 1, wherein the aperture is at least one of round dot, a rod, or a cross.

4. The system of claim 1, wherein the aperture does not extend to an edge of the PCB.

5. The system of claim 1, wherein a ratio of the area occupied by the apertures over the area of PCB outer surface ranges from about 6% to about 12%.

6. The system of claim 3, wherein the round dot has about a diameter about 1.3 mm.

7. The system of claim 3, wherein the rod comprises horizontal rods and vertical rods.

8. The system of claim 7, wherein the horizontal rod and vertical rods are about 4.1 mm and 3.1 mm in length respectively.

9. A LED system, comprising:
a substrate having a plurality of chipsets;
at least one LED mounted onto a surface of the substrate; and
an aperture through the substrate is interposed between the plurality of chipsets on the substrate and the at least one LED.

10. The LED system of claim 9, wherein the substrate is a PCB.

11. The LED system of claim 10, wherein the aperture is designed to reduce tension of the PCB so that PCB is easily bent.

12. The LED system of claim 9, wherein the aperture is filled with an insulating medium selected from a group comprising of air and a material which is softer than that of PCB board.

13. The LED system of claim 9, wherein the aperture does not extend to an edge of the PCB.

14. The LED system of claim 9, wherein the aperture is at least one of round dot, a rod, or a cross.

15. The LED system of claim 14, wherein the rod comprises horizontal rods and vertical rods.

16. The LED of claim 15, wherein a ratio of the area occupied by the apertures over the area of PCB outer surface ranges from about 6% to about 12%.

17. The LED system of claim 15, wherein the round dot has about a diameter about 1.3 mm.

18. A method, comprising:
cutting an aperture through a printed circuit board (“PCB”) via both sides to form a through hole, interposed between a location for a LED at a first side of the PCB and a location for a chipset on a second side PCB board.

19. The method of claim 18, wherein a ratio of the area occupied by the apertures over the area of PCB outer surface ranges from about 6% to about 12%.

20. The method of claim 18, further comprising reducing the tensile stress related to bending the PCB.
